(19) United States
(12) Patent Application Publication
(10) Pub. No.: US 2025/0101585 A1
(43) Pub. Date: Mar. 27, 2025

(54) FILM FORMING APPARATUS

(71) Applicant: Tokyo Electron Limited, Tokyo (JP)

(72) Inventors: Ryohei TAKAKI, Yamanashi (JP); Hiroo KAWASAKI, Yamanashi (JP)

(21) Appl. No.: 18/973,637

(22) Filed: Dec. 9, 2024

(30) Foreign Application Priority Data
Jun. 23, 2022 (JP) 2022-101410

(51) Int. Cl. C23C 16/455; C23C 16/44; C23C 16/52

(52) U.S. Cl. CPC C23C 16/45544; C23C 16/4412; C23C 16/45565; C23C 16/52

(57) ABSTRACT

A film forming apparatus includes: a processing container, a stage provided in the processing container in a liftable and lowerable manner; a shower head facing the stage and having a plurality of gas holes, a lifting and lowering mechanism configured to lift the stage when film formation is to be performed to form a processing space between the shower head and the stage, and a measurer configured to measure a gap between the shower head and the stage.

### CROSS-REFERENCE TO RELATED APPLICATIONS

This application is a continuation application of International Application No. PCT/JP2023/021581 filed on Jun. 9, 2023, and designated the U.S., which is based upon and claims priority to Japanese Patent Application No. 2022-101410 filed on Jun. 23, 2022, the entire contents of which are incorporated herein by reference.

### BACKGROUND

### 1. Technical Field

The present disclosure relates to a film forming apparatus.

### 2. Description of Related Art

For example, Japanese Unexamined Patent Publication No. 2020-200510 (hereinafter, “Patent Document 1”) proposes a substrate processing apparatus including a liftable mounting table provided in a processing container, a member which faces the mounting table and forms a processing space between the mounting table and the member, a gas supply unit that supplies a source gas and a reactant gas into the processing container, and a pressure regulating valve with an adjustable opening degree. The adjustment of the gap between the member forming the processing space and the mounting table affects a process performed in the processing space.

### SUMMARY

According to an aspect of the present disclosure, there is provided a film forming apparatus including a processing container, a stage provided in the processing container in a liftable and lowerable manner, a shower head facing the stage and having a plurality of gas holes, a lifting and lowering mechanism configured to lift the stage when film formation is to be performed to form a processing space between the shower head and the stage, and a measurer configured to measure a gap between the shower head and the stage.

### BRIEF DESCRIPTION OF THE DRAWINGS

FIG. 1 is a schematic cross-sectional diagram of a film forming apparatus according to an embodiment;

FIG. 2A is a diagram illustrating an example of a measurer according to the embodiment;

FIG. 2B is a diagram illustrating an example of the measurer according to the embodiment;

FIG. 3 is a diagram illustrating a configuration example of an eddy current sensor and the vicinity thereof according to the embodiment;

FIG. 4 is a flowchart illustrating an example of a film forming process according to the embodiment; and

FIG. 5 is a flowchart illustrating an example of a film forming process using an atomic layer disposition (ALD) method according to the embodiment.

### DETAILED DESCRIPTION

The present disclosure provides a film forming apparatus capable of accurately measuring a gap between a shower head and a stage, which make up a processing space.

Hereinafter, embodiments for implementing the present disclosure will be described with reference to the drawings. In the drawings, the same components are denoted by the same reference numerals, and a duplicate description thereof may be omitted.

In the present specification, a deviation in a direction such as parallel, perpendicular, orthogonal, horizontal, vertical, up and down, and left and right is allowed to the extent that the advantageous effect of the embodiment is not impaired. The shape of the corner portion is not limited to a right angle, and may be rounded in an arch shape or may be chamfered. Parallel, perpendicular, orthogonal, horizontal, vertical, circular, and coincident may include substantially parallel, substantially perpendicular, substantially orthogonal, substantially horizontal, substantially vertical, substantially circular, and substantially coincident.

### (Configuration Example of Film Forming Apparatus)

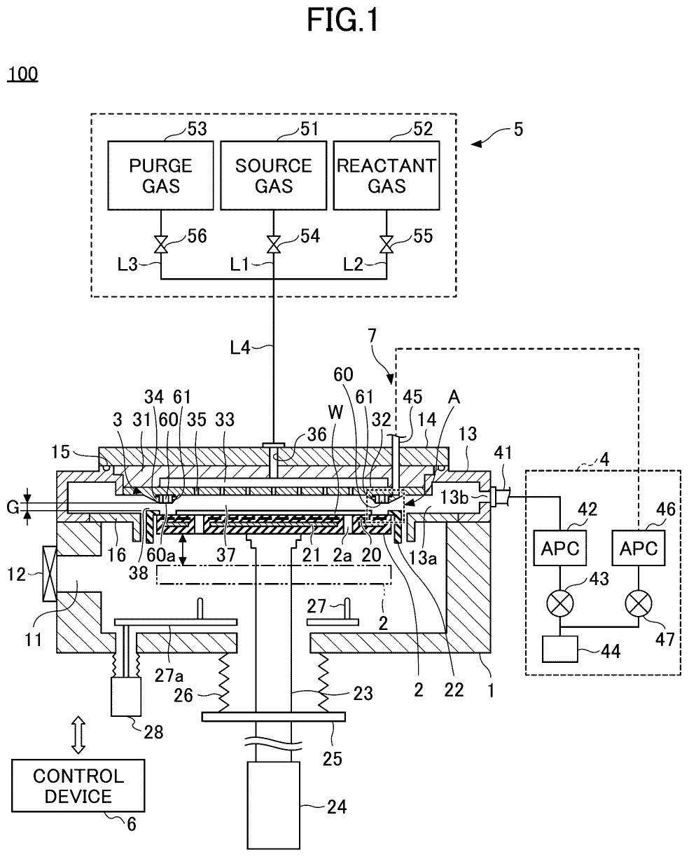

A film forming apparatus 100 according to the present embodiment will be described with reference to FIG. 1. FIG. 1 is a schematic cross-sectional diagram of the film forming apparatus 100 according to the present embodiment.

The film forming apparatus 100 is an apparatus configured to sequentially supply a source gas and a reactant gas to a substrate W, such as a wafer, to form a desired film on a surface of the substrate W. For example, as an example of a desired film, the film forming apparatus 100 forms a TiN film, which is a metal-containing film, on the surface of the substrate W by supplying a TiCl₄ gas as a source gas and an NH₃ gas as a reactant gas.

As illustrated in FIG. 1, the film forming apparatus 100 includes a processing container 1, a stage (substrate mounting table) 2, a shower head 3, an exhauster 4, a processing gas supply 5, and a control device 6. The processing container 1 is made of a metal, such as aluminum, and has a substantially cylindrical shape. A loading/unloading port 11 for loading and unloading the substrate W is formed in a sidewall of the processing container 1, and the loading/unloading port 11 can be opened and closed by a gate valve 12.

An annular exhaust duct 13 having a rectangular cross section is provided on the main body of the processing container 1. A slit 13a is formed along the inner peripheral surface of the exhaust duct 13. An exhaust port 13b is formed in the outer wall of the exhaust duct 13. A ceiling wall 14 is provided on the upper surface of the exhaust duct 13 so as to close the upper opening of the processing container 1. A seal ring 15 is provided between the ceiling wall 14 and the exhaust duct 13, and the inside of the processing container 1 is thereby air-tightly sealed. The partition member 16 vertically partitions the inside of the processing container 1 in the case where the stage 2 (and the outer ring 22) is lifted to a processing position, which is described later.

The stage 2 horizontally supports the substrate W in the processing container 1. The stage 2 is in the form of a disc having a size corresponding to the substrate W, and is supported by a support member 23. The stage 2 is made of a ceramic material, such as aluminum nitride (AlN) or a metal material such as aluminum or a nickel-based alloy, and a heater 21 for heating the substrate W is embedded in the stage 2. The heater 21 generates heat by being supplied with power from a heater power supply (not illustrated). The substrate W is controlled to have a predetermined temperature by controlling an output of the heater 21 in response to a temperature signal from a thermocouple (not illustrated) provided near the substrate mounting surface on the upper surface of the stage 2. The heater 21 is an example of a heating structure included in the stage 2. In an outer peripheral area of the substrate mounting surface of the stage 2, an outer ring 22 made of ceramics, such as alumina, is provided so as to cover a side surface of the stage 2.

A support member 23 extends from the center of the bottom surface of the stage 2 to the lower side of the processing container 1 through a hole formed in the bottom wall of the processing container 1, and the lower end of the support member 23 is connected to a lifting and lowering mechanism 24. The stage 2 can be lifted and lowered by the lifting and lowering mechanism 24 via the support member 23 between a processing position (indicated by a solid line in FIG. 1) and a transfer position (indicated by a two-dot dash line below the processing position) at which the substrate W can be transferred. A flange portion 25 is attached to the support member 23 below the processing container 1, and a bellows 26, which separates the atmosphere in the processing container 1 from the outside air and expands and contracts in accordance with the lifting and lowering movement of the stage 2, is provided between the bottom surface of the processing container 1 and the flange portion 25.

Three substrate support pins 27 (only two of which are illustrated) are provided in the vicinity of the bottom surface of the processing container 1 so as to protrude upward from a lifting and lowering plate 27a. The substrate support pins 27 can be lifted and lowered via the lifting and lowering plate 27a by a lifting and lowering mechanism 28 provided below the processing container 1, and can be protruded and retracted with respect to the upper surface of the stage 2 when being inserted into through holes 2a provided in the stage 2 at the transfer position. By lifting and lowering the substrate support pins 27 in this manner, the substrate W is transferred between a substrate transfer mechanism (not illustrated) and the stage 2.

A shower head 3 supplies a spray of a processing gas to the inside of the processing container 1. The shower head 3 is made of metal, faces the stage 2, and has substantially the same diameter as the stage 2. The shower head 3 includes a main body 31 fixed to the ceiling wall 14 of the processing container 1 and a shower plate 32 connected to a lower portion of the main body 31. A gas diffusion space 33 is formed between the main body 31 and the shower plate 32, and a gas introduction hole 36 is provided in the gas diffusion space 33 so as to penetrate the main body 31 and the center of the ceiling wall 14 of the processing container 1. A plurality of gas holes 35 are formed in the flat surface of the shower plate 32 in a central area. A protrusion 34 annularly protruding toward the stage 2 is formed on the outer periphery of the central area where the plurality of gas holes 35 are formed.

The stage 2 is provided in the processing container 1 in a liftable and lowerable manner, and the lifting and lowering mechanism 24 lifts the stage 2 to the processing position when film formation is to be performed. Thus, a processing space 37 is formed between the shower head 3 and the stage 2. In other words, in a state where the stage 2 is present at the processing position when film formation is performed, the processing space 37 is formed between the shower plate 32 and the stage 2, and the protrusion 34 is close to the upper surface of the stage 2 and the outer ring 22 to form an annular space 38. A gap (interval, distance) G between the shower head 3 (the protrusion 34 of the shower plate 32) and the stage 2 in a state where the stage 2 is present at the processing position is measured by a measurer A. In a state where the stage 2 is present at the processing position when film formation is performed, the gap G measured by the measurer A is, for example, about 3 mm.

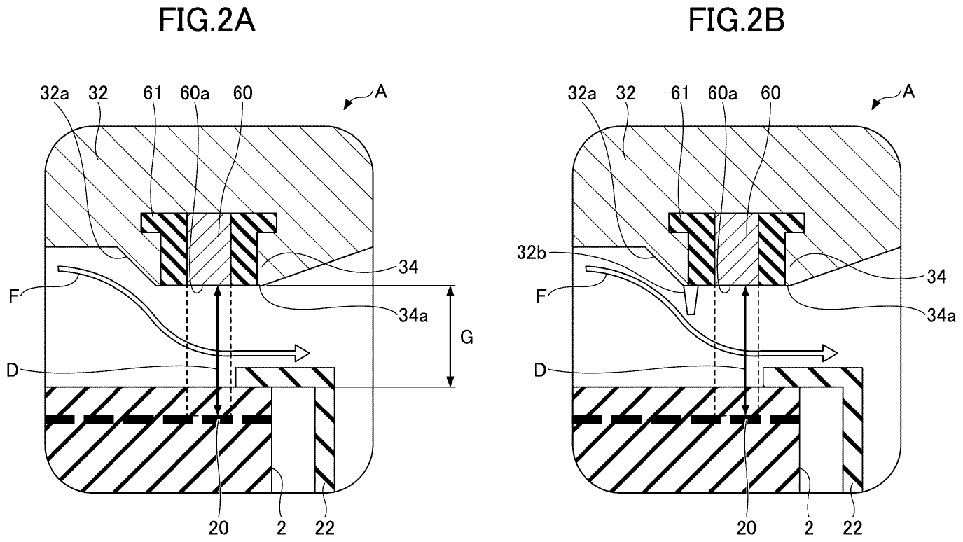

The measurer A includes an eddy current sensor 60 installed in the shower head 3 (the protrusion 34 of the shower plate 32) and a mesh electrode 20 provided in the stage 2 (see FIGS. 1 and 2A). The eddy current sensor 60 is covered with a cover member 61. The cover member 61 is an insulator and covers at least the side surface of the eddy current sensor 60. The measurer A further includes an exhaust pipe 45 for vacuum-exhausting a space around the eddy current sensor 60 in the shower head 3. The measurer A will be described in detail later.

The exhauster 4 exhausts the inside of the processing container 1. The exhauster 4 includes an exhaust pipe 41 connected to an exhaust port 13b of the exhaust duct 13, an auto pressure controller (APC) valve 42, an opening and closing valve 43, and a vacuum pump 44. One end of the exhaust pipe 41 is connected to the exhaust port 13b of the exhaust duct 13, and the other end is connected to a suction port of the vacuum pump 44. The APC valve 42 and the opening and closing valve 43 are provided between the exhaust duct 13 and the vacuum pump 44 in this order from the upstream side. The APC valve 42 adjusts a pressure in the processing space 37 by adjusting a conductance of the exhaust path. The opening and closing valve 43 switches between opening and closing of the exhaust pipe 41. When the processing is performed, the partition member 16 and the stage 2 (outer ring 22) partition the inside of the processing container 1 into an upper space including the processing space 37 and a lower space on the rear surface side of the stage 2. Thus, the gas in the processing space 37 reaches the annular space inside the exhaust duct 13 via the annular space 38 and the slit 13a, and is exhausted from the exhaust port 13b of the exhaust duct 13 through the exhaust pipe 41 by the vacuum pump 44 of the exhauster 4. The lower space is brought into a purge atmosphere by a purge gas supply mechanism (not illustrated). Therefore, the gas in the processing space 37 does not flow into the lower space.

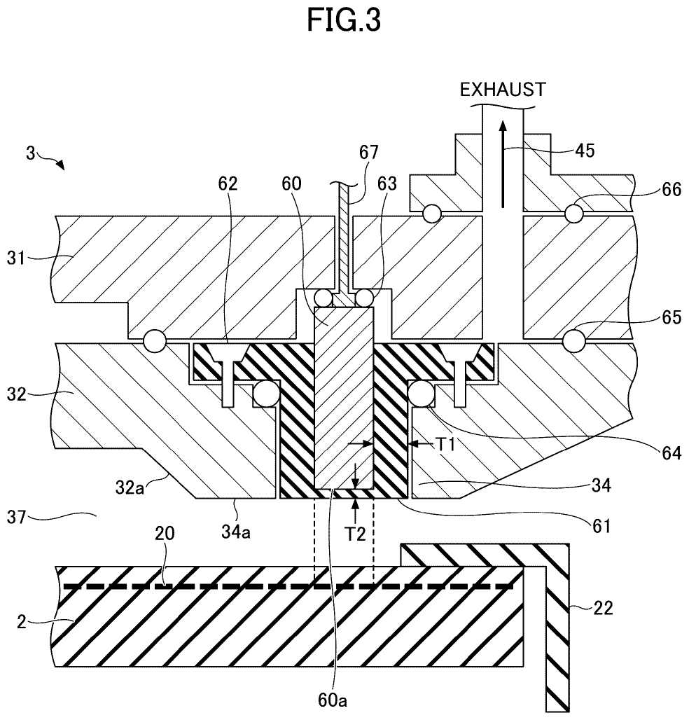

The film forming apparatus 100 further includes an exhaust mechanism 7 configured to vacuum-exhaust the space around the eddy current sensor 60 in the shower head 3. The exhaust mechanism 7 includes an exhaust pipe 45 (see FIGS. 1 and 3). The exhauster 4 includes an APC valve 46 connected to the exhaust pipe 45, and an opening and closing valve 47. The exhaust pipe 45 is connected to the suction port of the vacuum pump 44. The APC valve 46 and the opening and closing valve 47 are provided between the exhaust duct 45 and the vacuum pump 44 in this order from the upstream side. The APC valve 46 adjusts a pressure of a space around the eddy current sensor 60 by adjusting a conductance of the exhaust path. The opening and closing valve 47 switches between opening and closing of the exhaust pipe 45. The gas in the space around the eddy current sensor 60 is exhausted by the vacuum pump 44 via the exhaust pipe 45.

The processing gas supply 5 includes a source gas supply line L1, a reactant gas supply line L2, a purge gas supply line L3, and a junction pipe L4. The junction pipe L4 is connected to the gas introduction hole 36. The source gas supply line L1 extends from a source gas supply source 51 and is connected to the junction pipe L4. A mass flow controller (not illustrated) and an opening and closing valve 54 are provided in the source gas supply line L1 in this order from the source gas supply source 51 side. The mass flow controller controls the flow rate of a source gas flowing through the source gas supply line L1. The opening and closing valve 54 switches between supplying and stopping the source gas when an atomic layer deposition (ALD) process is performed. A buffer tank (not illustrated) may be provided between the mass flow controller and the opening and closing valve 54. The buffer tank temporarily stores the source gas and supplies a necessary source gas in a short time.

The reactant gas supply line L2 extends from a reactant gas supply source 52 and is connected to the junction pipe L4. A mass flow controller (not illustrated) and an opening and closing valve 55 are provided in the reactant gas supply line L2 in this order from the source gas supply source 52 side. The mass flow controller controls the flow rate of a reactant gas flowing through the reactant gas supply line L2. The opening and closing valve 55 switches between supplying and stopping the source gas when an ALD process is performed. A buffer tank (not illustrated) may be provided between the mass flow controller and the opening and closing valve 55. The buffer tank temporarily stores the reactant gas and supplies a necessary reactant gas in a short time.

The purge gas supply line L3 extends from the purge gas supply source 53 and is connected to the junction pipe L4. A mass flow controller (not illustrated) and an opening and closing valve 56 are provided in the purge gas supply line L3 in this order from the purge gas supply source 53 side. The mass flow controller controls the flow rate of a purge gas flowing through the purge gas supply line L3. The opening and closing valve 56 switches between supplying and stopping the purge gas when an ALD process is performed. A buffer tank (not illustrated) may be provided between the mass flow controller and the opening and closing valve 56. The buffer tank temporarily stores the purge gas and supplies a necessary purge gas in a short time.

Thus, an N₂ gas is supplied to the junction pipe L4 through the purge gas supply line L3. The purge gas supply line L3 constantly supplies the N₂ gas during the film formation by the ALD method. An orifice (not illustrated) is provided between the opening and closing valve 56 and the junction pipe L4 to prevent the purge gas from flowing back to the purge gas supply line L3.

The control device 6 controls an operation of each part of the film forming apparatus 100. The control device 6 includes a central processing unit (CPU), a read only memory (ROM), and a random access memory (RAM). The CPU executes a desired process according to a recipe stored in a storage area, such as the RAM. In the recipe, control information of the apparatus for process conditions is set. The control information may be, for example, a gas flow rate, a pressure, a temperature, and a process time. The recipe and the programs used by the control device 6 may be stored in, for example, a hard disk or a semiconductor memory. The recipe and the like may be stored in a portable computer-readable storage medium such as a CD-ROM or a DVD, and may be set at a predetermined position and read.

### (Measurer)

Next, the measurer A will be described with reference to FIGS. 2A and 2B. FIGS. 2A and 2B are diagrams illustrating an example of the measurer A according to the embodiment. As illustrated in FIG. 1, the uniformity of a specific electric resistance and a film thickness can be improved by lifting and lowering the stage 2 to narrow the gap G between the shower head 3 and the stage 2 when the film formation is performed, and the coverage when the film formation is performed can be improved. However, the narrower the gap G is controlled to be, the larger an influence of a slight control error for the gap G has on the process (substrate processing).

Accordingly, in the film forming apparatus 100 of the present disclosure, the gap G is accurately measured by the measurer A. As illustrated in FIG. 2A, the measurer A includes an eddy current sensor 60 and a mesh electrode 20. The eddy current sensor 60 is installed in an annular protrusion 34 protruding from the shower plate 32 toward the stage 2, and detects the mesh electrode 20 in the stage 2. The eddy current sensor 60 has a coil, generates a high-frequency magnetic field, and measures a distance D by a phenomenon in which an eddy current flows in a direction perpendicular to the passage of a magnetic flux in the mesh electrode 20 due to an electromagnetic induction action when a measurement target (the mesh electrode 20 in FIGS. 2A and 2B) is present in the magnetic field. The distance D is a distance between the detection surface 60a of the eddy current sensor 60 and the surface of the mesh electrode 20, and the gap G between the shower head 3 and the stage 2 can be accurately measured by the distance D.

The eddy current sensor 60 is provided so as not to interfere with a flow F of the gas discharged from the plurality of gas holes 35 (see FIG. 1). Therefore, the side surface of the protrusion 34 on the radially inner side is a tapered surface 32a that widens toward the outer side, and the eddy current sensor 60 is disposed on the outer peripheral side of the protrusion 34 relative to the tapered surface 32a. Thus, the detection surface 60a of the eddy current sensor 60 is directed in substantially the same direction as the gas flow F discharged from the plurality of gas holes 35, and the gas flow F can be produced in a direction away from the detection surface 60a of the eddy current sensor 60. As a result, it is possible to prevent a film from being formed on the detection surface 60a and, in turn, prevent the measurement function of the eddy current sensor 60 from being deteriorated.

For example, three eddy current sensors 60 may be attached at intervals of 120° in the circumferential direction of the annular protrusion 34. The number of eddy current sensors 60 may be one or more, preferably three or more. By providing three or more eddy current sensors 60 in the protrusion 34 and obtaining a difference between the measurement values of the gap G at three or more positions, the inclination of the stage 2 can be measured with higher accuracy.

The eddy current sensor 60 is provided in the shower head 3 and is not disposed in the stage 2. An upper limit of the temperature at which the eddy current sensor 60 can be correctly used is about 200° C. in consideration of the heat resistance of the eddy current sensor 60, but on the other hand, the stage 2 is heated by the heater 21 to 400° C. or higher when film formation is performed. Therefore, the eddy current sensor 60 cannot be installed on the stage 2 side.

Furthermore, if the eddy current sensor 60 were to be disposed in the stage 2, a film would be formed on the eddy current sensor 60 as well as on a substrate W placed on the stage 2, and as a consequence, the detection function of the eddy current sensor 60 would be degraded, and the gap G would not be able to be correctly measured. If the film on the eddy current sensor 60 were to be removed by cleaning, the eddy current sensor 60 would be exposed to a cleaning gas, and the eddy current sensor 60 would be damaged. Therefore, the eddy current sensor 60 cannot be installed on the stage 2 side.

In the film forming apparatus 100 of the present disclosure, the eddy current sensor 60 is disposed in the shower head 3, and is not installed on the stage 2 side. For this reason, the eddy current sensor 60 can be used in an environment of 200° C. or lower. The eddy current sensor 60 is disposed on the outer peripheral side of the tapered surface 32a on the side of the shower head 3 away from the stage 2 so that no film is formed on the eddy current sensor 60, and so that the direction of the gas flow F is away from the detection surface 60a of the eddy current sensor 60. Thus, accurate measurement of the gap G can be performed without deteriorating the detection function of the eddy current sensor 60 and without being affected by thermal expansion and contraction of the member on which the eddy current sensor 60 is disposed or by the mechanical variation of the member.

The eddy current sensor 60 constantly monitors the state of the gap G. Thus, by detecting the inclination of the stage 2, in the case of occurrence of an abnormality, such as deterioration or breakage of a belt used for power transmission of the lifting and lowering mechanism 24, loosening of a lock nut of a linear guide, or loosening of various screws, the abnormality can be found at an early stage. Thus, when the stage 2 is inclined by a reference value or more, it is determined that there is an abnormality, and the processing of the substrate W is stopped, whereby the substrate W is prevented from being continuously processed, and the generation of defective substrates W that have to be discarded can be reduced.

Although there are individual differences in the attachment of the eddy current sensor 60 to the shower head 3 and the position of the mesh electrode 20 in the stage 2, the individual differences can be canceled out by performing a zero point adjustment of the eddy current sensor 60 when the gap G is adjusted.

The mesh electrode 20 is an example of a metal member provided on the stage 2 side so as to face the eddy current sensor 60. A metal electrode disposed to face the eddy current sensor 60 is not limited to the mesh electrode 20. A plate-shaped electrode may be embedded in the stage 2 instead of the mesh electrode 20. The metal member may be a metal film formed on the surface of the stage 2. The outer ring 22 may be disposed at a position facing the eddy current sensor 60, and the metal member may be a mesh electrode or a plate-shaped electrode embedded in the outer ring 22, or a metal film formed on the surface of the outer ring 22. However, in the case where the metal member is a metal film, the metal film needs to be a film having resistance to a cleaning gas. Since the outer ring 22 is more easily replaceable than the stage 2, in the case where there is a need of replacing the metal member, it is preferable to provide the metal member on the outer ring 22 rather than the stage 2.

As described above, the metal member is provided at a position of the stage 2 or the outer ring 22 so as to face at least the eddy current sensor 60. The metal member is formed of, for example, molybdenum or other metals.

The mesh electrode 20 or the plate-shaped electrode embedded in the stage 2 or the outer ring 22 may be disposed on the entire surface of the stage 2 or the like, or may be disposed at a position facing the eddy current sensor 60 of the stage 2 or the like without needing to be disposed on the entire surface. The mesh electrode 20 or the plate-shaped electrode may be used also as a radio frequency (RF) electrode for applying RF power. In this case, it is preferable to dispose the mesh electrode 20 or the plate-shaped electrode on the entire surface of the stage 2. The gap G can be measured by the eddy current sensor 60 using the mesh electrode 20 or the plate-shaped electrode when RF power is not supplied to the mesh electrode 20 or the plate-shaped electrode.

The mesh electrode 20 or the like may be used also as a heater wire. In this case as well, it is preferable to dispose the mesh electrode 20 or the plate-shaped electrode on the entire surface of the stage 2. The gap G can be measured by the eddy current sensor 60 using the mesh electrode 20 or the like when the voltage for heating the heater is not supplied to the mesh electrode 20 or the like.

The eddy current sensor 60 is covered with a cover member 61. The cover member 61 is formed of a ceramic, such as Al₂O₃, AlN, or silica (SiO₂). By covering the side surface of the eddy current sensor 60 with the ceramic cover member 61, it is possible to prevent gas from entering through the gap between the eddy current sensor 60 and the shower plate 32, and to avoid the gas flow F from being disturbed in the vicinity of the eddy current sensor 60.

A space has often been provided in the area close to the eddy current sensor 60 to avoid an erroneous detection, which is caused by the presence of a metal-made member in the proximity of the side surface of the eddy current sensor 60. However, provision of a space in the area close to the eddy current sensor 60 disposed in the protrusion 34 is not actually preferable, as such a space disturbs the gas flow F and causes the eddy current sensor 60 to be exposed to the source gas, the reactant gas, and the cleaning gas.

Under such a circumstance, covering the side surface of the eddy current sensor 60 with the ceramic cover member 61 can prevent the eddy current sensor from detecting metal in the shower plate 32 on the side surface of the eddy current sensor 60. Due to this, erroneous detection can be prevented and the metal in the mesh electrodes 20 can be detected with the detection surface 60a of the eddy current sensor 60, so that the gap G can be correctly measured.

As described above, it is possible to prevent detection of metal in the shower plate 32 on the side surface of the eddy current sensor 60 by providing a space between the eddy current sensor 60 and the shower plate 32 without providing the cover member 61 in the vicinity of the eddy current sensor 60. However, in this case, the gas enters the space around the eddy current sensor 60, and a (unnecessary) film is formed on the eddy current sensor 60. As a result, the eddy current sensor 60 is damaged when the film formed on the eddy current sensor 60 is removed by the cleaning gas.

Therefore, by covering the eddy current sensor 60 with the cover member 61, it is possible to prevent erroneous detection and to prevent film formation on the eddy current sensor 60. In addition, by providing the cover member 61 so as to cover the eddy current sensor 60, it is possible to suppress the influence of radiant heat from the stage 2 on the eddy current sensor 60 and to suppress temperature rise in the eddy current sensor 60.

The lower surface of the cover member 61 is flush with the protruding surface 34a of the protrusion 34 of the shower plate 32. The detection surface 60a of the eddy current sensor 60 may be flush with the protruding surface 34a of the protrusion 34, or may be recessed inward from the protruding surface 34a.

As illustrated in FIG. 2B, eaves 32b for preventing gas from adhering to the eddy current sensor 60 may be provided between the tapered surface 32a and the detection surface 60a of the eddy current sensor 60. The eaves 32b may be provided on the entire circumference in the circumferential direction on the radially inner side of the eddy current sensor 60 of the protrusion 34 and on the circumferentially outer side of the tapered surface 32a.

### (Configuration Example of Eddy Current Sensor and Vicinity Thereof)

Next, an example of the configuration of the eddy current sensor 60 and the vicinity thereof according to the embodiment will be further described with reference to FIG. 3. As illustrated in FIG. 3, the eddy current sensor 60 disposed in the protrusion 34 may be covered with a cover member 61 not only on the side surface but also on the detection surface 60a. This can prevent a film from being formed on the side surface and the detection surface 60a of the eddy current sensor 60.

Normally, a thickness T1 of the side portion of the cover member 61 is preferably 0.75 to 1.0 times or more the diameter of the eddy current sensor, but an appropriate thicknesses can be adopted depending on the specifications of the eddy current sensor. A thickness T2 of the tip portion of the cover member 61 covering the detection surface 60a is smaller than the thickness T1 of the side portion, and may be 0.5 mm or more and 2.0 mm or less.

By disposing the eddy current sensor 60 on the shower plate 32, the eddy current sensor 60 becomes a singular point of temperature, and the temperature distribution in the processing space 37 (see FIG. 1) changes, which may affect the processing of the substrate W (film formation). Therefore, it is desirable to reduce the size of the eddy current sensor 60 as much as possible. Miniaturization of the eddy current sensor 60 is preferable, because the more the eddy current sensor 60 is reduced in size, the weaker the high-frequency magnetic field generated from the eddy current sensor 60 becomes, and it is thereby possible to make the thickness T1 of the side portion of the cover member 61 thinner.

However, if the eddy current sensor 60 were to be miniaturized and the thickness T2 of the tip portion of the cover member 61 were to be made as thin as 0.5 mm or more and 2.0 mm or less, the tip portion of the cover member 61 would be easily broken because of its thinness. In particular, a cable 67 connected to the eddy current sensor 60 needs to be wired to the atmosphere side. In other words, the cable 67 of the eddy current sensor 60 is in the atmospheric space. In contrast, the processing space 37 is a vacuum space. For this reason, if the tip portion of the cover member 61 screwed to the shower plate 32 by the screw 62 were to serve as a plate for partitioning the atmosphere and the vacuum, the tip portion of the cover member 61 might be broken due to a pressure difference between the atmosphere and the vacuum.

Therefore, in order to prevent the tip portion of the cover member 61 from being broken, a seal ring 63, such as an O-ring, is provided between the cable 67 and the eddy current sensor 60 to partition the atmosphere and the vacuum, thereby sealing the eddy current sensor 60 and cover member 61 side from the atmospheric space in which the cable 67 extends and making the cover member 61 side a vacuum section. Furthermore, by providing a seal ring 64 between the cover member 61 and the shower plate 32, and a seal ring 65 between the shower plate 32 and the main body 31, it is possible to suppress leakage of the source gas, the reactant gas, and the cleaning gas supplied to the processing space 37 or the gas diffusion space 33, and leakage of these gases flowing in the vicinity of the slit 13a. Furthermore, by providing a seal ring 66 between the main body 31 and the exhaust pipe 45, mixture of the atmosphere into the vicinity of the eddy current sensor 60 and the cover member 61 is suppressed.

Although the eddy current sensor 60 and the cover member 61 are isolated from the atmosphere and the processing space 37 with regard to fluid, the atmosphere may remain around the eddy current sensor 60 and the cover member 61 due to assembly in the atmospheric state, or the atmosphere may be mixed in due to the permeation of the atmosphere through the seal ring. If the processing space 37 were to be evacuated as it is, the thin tip portion of the cover member 61 might be damaged due to the pressure difference between the processing space 37 and the atmosphere around the eddy current sensor 60 and the cover member 61. For this reason, the space around the eddy current sensor 60 and the cover member 61 in the shower head 3 is vacuum-exhausted by the vacuum pump 44 through the exhaust pipe 45, so that the pressure difference between the processing space 37 and the space around the eddy current sensor 60 and the cover member 61 is eliminated, and it is thus possible to suppress an excessive load from being applied to the front end portion of the cover member 61.

The exhaust amount may be determined according to, for example, the cross-sectional area of the exhaust pipe 45, and the exhaust amount from the exhaust pipe 45 and the exhaust amount from the exhaust pipe 41 (see FIG. 1) may be controlled to adjust the pressure in the processing space 37 and the pressure around the eddy current sensor 60 and the cover member 61 to be substantially the same pressure. For example, the conductance of the exhaust pipe 45 may be adjusted in such a manner that the pressure in the processing space 37 and the pressure around the eddy current sensor 60 and the cover member 61 are substantially the same pressure. The opening degree of the APC valve 46 may be adjusted in such a manner that the pressure in the processing space 37 and the pressure around the eddy current sensor 60 and the cover member 61 are substantially the same pressure. This can prevent the cover member 61 from being broken by the atmospheric pressure. The exhaust from the exhaust pipe 45 may be performed by using the vacuum pump 44 or a vacuum pump different from the vacuum pump 44.

### (ALD Apparatus)

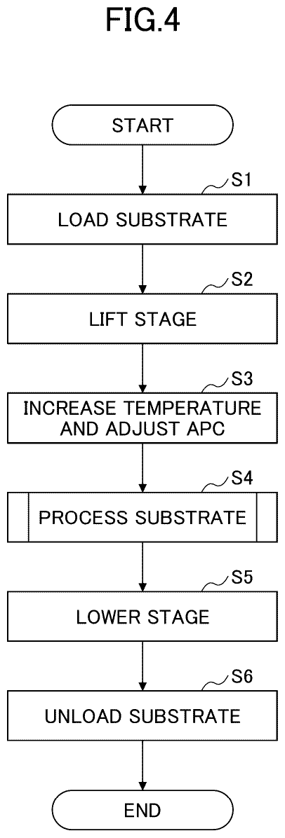

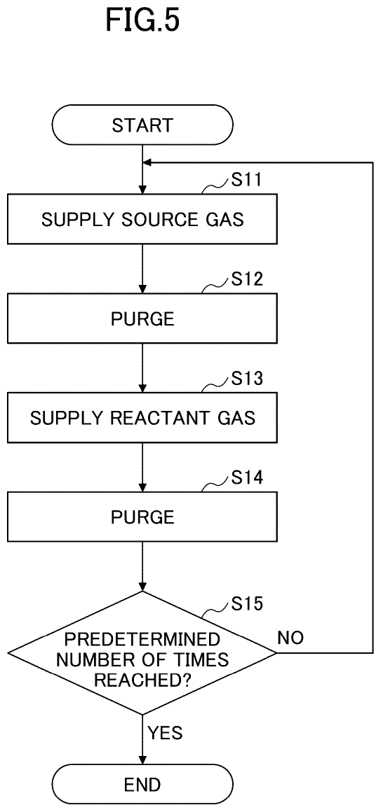

The film forming apparatus 100 described above is, for example, an atomic layer deposition (ALD) apparatus and can perform a film forming process (substrate processing) using an ALD method. An example of a film forming process using an ALD method performed by the film forming apparatus 100 will be described with reference to FIGS. 4 and 5. FIG. 4 is a flowchart illustrating an example of a film forming process according to the embodiment. FIG. 5 is a flowchart illustrating an example of a film forming process using an ALD method according to the embodiment.

In step S1, a substrate W is loaded into the processing container 1 of the film forming apparatus 100. Specifically, the gate valve 12 is opened, with the stage 2 heated to a predetermined temperature (for example, 300° C. to 700° C.) by the heater 21 being lowered to the transfer position (indicated by a two-dot dash line in FIG. 1). Subsequently, the substrate W is loaded into the processing container 1 through the loading/unloading port 11 by a transfer arm (not illustrated) and is supported by the substrate support pins 27. After the transfer arm is retracted from the loading/unloading port 11, the gate valve 12 is closed. The substrate support pins 27 are lowered to place the substrate W on the stage 2.

Next, in step S2, the control device 6 controls the lifting and lowering mechanism 24 to lift the stage 2 to a processing position (the position of the stage 2 indicated by the solid line in FIG. 1). Thus, the inside of the processing container 1 is partitioned into an upper space, which is a space on the front surface (substrate mounting surface) side of the stage 2 including the processing space 37, and a lower space, which is a space on the rear surface side of the stage 2.

Next, in step S3, the temperature of the substrate W on the stage 2 is increased, and the opening degrees of the APC valves 42 and 46 are adjusted. In other words, the temperature of the substrate W on the stage 2 is increased to a predetermined temperature (for example, 300° C. to 700° C.) by the heater 21. The control device 6 controls the exhauster 4 to adjust the inside of the processing container 1 to a predetermined degree of vacuum. The control device 6 controls the exhauster 4 to adjust the pressure around the eddy current sensor 60 and the cover member 61 to be substantially the same as the pressure in the processing space 37.

Thereafter, the control device 6 opens the opening and closing valve 56 of the processing gas supply 5 and closes the opening and closing valves 54 and 55. Thus, the purge gas is supplied from the purge gas supply source 53 into the processing space 37 through the purge gas supply line L3 and the junction pipe L4. Further, the control device 6 adjusts the opening degree of the APC valve 42 such that the pressure in the processing space 37 becomes a desired pressure, based on a pressure sensor (not illustrated) for detecting the pressure in the processing space 37. The opening degree of the APC valve 46 is adjusted in such a manner that the pressure around the eddy current sensor 60 is substantially the same as the pressure in the processing space 37.

Next, in step S4, the substrate W is processed. Specifically, first, in step S11 of FIG. 5, the control device 6 opens the opening and closing valve 54 to supply the source gas from the source gas supply source 51 into the processing space 37 through the source gas supply line L1 and the junction pipe L4, and exposes the substrate W to the source gas to form an atomic layer of the source gas on the substrate W.

Next, in step S12, the control device 6 closes the opening and closing valves 54. Thus, the source gas in the processing space 37 is discharged by the purge gas supplied from the purge gas supply source 53 into the processing space 37.

Next, in step S13, the control device 6 opens the opening and closing valve 55 to supply the reactant gas from the reactant gas supply source 52 into the processing space 37 through the reactant gas supply line L2 and the junction pipe L4, and causes the reactant gas to react with the atomic layer of the source gas on the substrate W to form a desired film.

Next, in step S14, the control device 6 closes the opening and closing valve 55. Thus, the reactant gas in the processing space 37 is discharged by the purge gas supplied from the purge gas supply source 53 into the processing space 37.

In step S15, it is determined whether the processing of steps S11 to S14 has been performed a predetermined number of times, and the processing of steps S11 to S14 is repeated until it is determined that the processing has been performed the predetermined number of times. When it is determined that the processing has been performed the predetermined number of times, the substrate processing of FIG. 5 is ended, and the process returns to step S4 of FIG. 4.

For example, a TiN film is formed on the substrate W in the case where the source gas is a TiCl₄ gas, the reactant gas is an NH₃ gas, and the purge gas is an N₂ gas. In the purge step, the reactive products (NH₄Cl gas, HCl gas), excess TiCl₄ gas, NH₃ gas, and the like are discharged.

When the substrate processing illustrated in FIG. 5 is completed in step S4 of FIG. 4, the process proceeds to step S5 of FIG. 4, and the control device 6 controls the lifting and lowering mechanism 24 to lower the stage 2 to the transfer position.

Next, in step S6, the substrate W is unloaded from the processing container 1 of the film forming apparatus 100. Specifically, the substrate support pins 27 are raised to lift the substrate W placed on the stage 2, and the substrate W is supported by the substrate support pins 27. The gate valve 12 is opened. Subsequently, the substrate W is unloaded from the processing container 1 through the loading/unloading port 11 by the transfer arm (not illustrated). After the transfer arm is retracted from the loading/unloading port 11, the gate valve 12 is closed. Thus, the process of forming a desired film (e.g., a TiN film) on the substrate W in the film forming apparatus 100 is completed.

As described above, the film forming apparatus 100 of the present embodiment performs a film forming process. At this time, the film forming apparatus 100 can accurately measure the gap G between the shower head 3 and the stage 2 which make up the processing space 37. Thus, if the measured value of the gap G is within an allowable range of deviation from a set value (target value), the substrate processing may be continued, and if the measured value is out of the allowable range, the substrate processing may be interrupted to unload the substrate W. The inclination of the stage 2 may be calculated from the measured value of the gap G, and if the calculated inclination of the stage 2 is out of the allowable range, the substrate processing may be performed after correcting the inclination of the stage 2 so that the inclination of the stage 2 is eliminated, or the substrate processing may be interrupted to unload the substrate W.

The film forming apparatus according to the embodiment disclosed herein is merely an example in all respects and should not be construed as being limited thereto. The embodiments may be modified and improved in various forms without departing from the scope and spirit of the appended claims. The matters described in the plurality of embodiments can be combined with each other within a range not inconsistent with each other.

For example, in the above-described embodiment, the example of the film forming process by the ALD method is described, but the present disclosure may be applied to various film forming processes such as a chemical vapor deposition (CVD) method or a sequential flow deposition (SFD) method.

What is claimed is:

1. A film forming apparatus, comprising:
a processing container;
a stage provided in the processing container in a liftable and lowerable manner;
a shower head facing the stage and having a plurality of gas holes;
a lifting and lowering mechanism configured to lift the stage when film formation is to be performed, to form a processing space between the shower head and the stage; and
a measurer configured to measure a gap between the shower head and the stage.

2. The film forming apparatus according to claim 1, wherein
the measurer includes
an eddy current sensor installed in the shower head, and
a metal member provided in the stage or in an outer peripheral member disposed at an outer periphery of the stage.

3. The film forming apparatus according to claim 2, wherein
the eddy current sensor is installed in a protrusion annularly protruding from an outer peripheral surface of an area of the shower head in which the plurality of gas holes are formed.

4. The film forming apparatus according to claim 3, wherein
a side surface on a radially inner side of the protrusion is a tapered surface that widens toward an outer side, and
the eddy current sensor is disposed in such a manner that the tapered surface causes a direction of a flow of a gas discharged from the plurality of gas holes to be away from a detection surface of the eddy current sensor.

5. The film forming apparatus according to claim 4, wherein
eaves for preventing a gas from adhering to the eddy current sensor are provided between the tapered surface and the eddy current sensor.

6. The film forming apparatus according to claim 2, wherein
the metal member is a metal electrode provided at a position, facing the eddy current sensor, on or in the stage or the outer peripheral member.

7. The film forming apparatus according to claim 6, wherein
the metal electrode is a mesh electrode or a plate-shaped electrode embedded in the stage or the outer peripheral member.

8. The film forming apparatus according to claim 6, wherein
the metal electrode is a metal film formed on a surface of the stage or a surface of the outer peripheral member.

9. The film forming apparatus according to claim 2, comprising:
a cover member made of an insulator and covering at least a side surface of the eddy current sensor.

10. The film forming apparatus according to claim 2, comprising:
an exhaust mechanism configured to vacuum-exhaust a space around the eddy current sensor in the shower head.

11. The film forming apparatus according to claim 1, wherein
the film forming apparatus is an ALD apparatus.
